(19) United States
(12) Patent Application Publication
(10) Pub. No.: US 2004/0021176 A1
(43) Pub. Date: Feb. 5, 2004

(54) Integrated circuit device and electronic device

(75) Inventor: Isao Tottori, Tokyo (JP)

Correspondence Address: BURNS, DOANE, SWECKER & MATHIS, L.L.P., P.O. Box 1404, Alexandria, VA, 22313-1404, US

(73) Assignee: RENESAS TECHNOLOGY CORPORATION

(21) Appl. No.: 10/606,828

(22) Filed: Jun. 27, 2003

(30) Foreign Application Priority Data
Jul. 30, 2002 (JP) 2002-221706
Feb. 7, 2003 (JP) 2003-31130

(51) Int. Cl. H01L 27/01

(52) U.S. Cl. 257/347

(57) ABSTRACT

An integrated circuit device has an integrated circuit (2) formed on a front surface of a silicon substrate (1), an insulating layer (12) formed on a rear surface of the substrate (1), and connection piles (4) penetrating the substrate (1), the integrated circuit (2), and the insulating layer (12).

An electronic device has plural integrated circuit devices (5a,5b) laminated in a multilayer structure, in which a connection pile (4a) formed in an integrated circuit (2a) in the device (5a) as an upper position in the multilayer structure is electrically connected to a connection pile (4b) formed in an integrated circuit (2b) as a lower position under a requirement of an electric connection for the piles (4a,4b) The pile (4a) is electrically insulated from the pile (4b) through the insulating layer (12) under no requirement of the electric connection for them.

### BACKGROUND OF THE INVENTION

1. Field of the Invention

The present invention relates to an integrated circuit device having a connection pile to be electrically connected to a connection pile formed in another integrated circuit device, and further relates to an electronic device made up of a plurality of integrated circuit devices laminated in a multilayer structure, which are electrically connected together through the connection piles.

2. Description of the Related Art

FIG. 1 is a vertical sectional view of a conventional integrated circuit device. FIG. 2 is a vertical sectional view of a conventional electronic device having two conventional integrated circuit devices which are laminated. In FIG. 1, reference number 105 designates the conventional integrated circuit device, 101 denotes a silicon substrate of a thinned film, and 102 indicates an integrated circuit formed on the silicon substrate 101. Reference number 103 designates a plurality of connection holes which penetrate both the silicon substrate 101 and the integrated circuit 102. Reference number 104 denotes each connection pile made of a conductive substance with which each connection hole 103 is filled.

Next, a description will now be given of a fabrication process of the conventional integrated circuit device and the electronic device fabrication process in which a plurality of the conventional integrated circuit devices are laminated and electrically connected together.

Such an integrated circuit device having the structure shown in FIG. 1 has a function to increase a degree of the integration by laminating the plural integrated circuit devices in a multilayer structure, and also has a function of bringing together the total functions of those integrated circuits formed in the integrated circuit devices.

The connection pile 104 is formed so as to electrically connect circuits formed in the integrated circuits 102 on the different integrated circuit devices.

In the fabrication process for the integrated circuit device shown in FIG. 1, the integrated circuit 102 is formed on the silicon substrate 101. A memory circuit or a logic circuit is, for example, formed in the integrated circuit 102. Following, one or more connection holes 103 are formed in each integrated circuit 102 according to the requirement of the electric connection between the integrated circuits 102 in the different layers of the multilayer structure. The connection piles 104 are then formed in the connection holes 103.

Following, a part of the rear surface of the silicon substrate 101 is eliminated, so that the thickness of the silicon substrate 101 becomes thinned. Thereby, the thinned integrated circuit device 105 is obtained.

Further, as shown in FIG. 2, each integrated circuit device is laminated on the other integrated circuit device, so that the electronic device of the multilayer structure made up of the plural integrated circuit devices is formed. In this case, there is a demand to electrically connect the circuit formed in one integrated circuit 102a in the integrated circuit device 105a to a circuit formed in the other integrated circuit 102b in the integrated circuit device 105b, the connection pile 104a is formed in the integrated circuit device 105a. The circuit formed in the integrated circuit 102a is electrically connected to the connection pile 104a. The connection pile 104b is also formed in the integrated circuit device 105b. The circuit formed in the integrated circuit 102b is electrically connected to the connection pile 104b. The integrated circuit device 105a is laminated on the integrated circuit device 105b so that the connection pile 104a is electrically connected to the connection pile 104b.

Thus, when the integrated circuits 102a and 102b are formed in the integrated circuit devices 105a and 105b, respectively, which are laminated together, a pair of the circuits in the devices 105a and 105b are electrically connected together according to the demand of the electrical connection.

Because the thinned integrated circuit device 105 can be formed using the silicon substrate 101 of a thin film, it is possible to adequately reduce the thickness of the integrated circuit device 105.

Since the conventional integrated circuit device has the configuration described above, the surface portion of the silicon substrate 101 as a non-thinned film exposed to the atmosphere is changed to a silicon dioxide by chemical reaction, so that this surface portion of the silicon substrate 101 becomes a non-conductor. When the thickness of the silicon substrate becomes thinned so as to reduce the entire thickness of the integrated circuit device, the surface portion of the silicon dioxide is eliminated from the silicon substrate 101, and a remained surface portion of the thinned silicon substrate 101 becomes conductivity.

As shown in FIG. 2, when the integrated circuit device 105a is laminated on the integrated circuit device 105b under no requirement of the electrical connection between the connection pile 104c in the integrated circuit device 105a and the connection pile 104d in the integrated circuit device 105b and the connection piles 104c and 104d are closed in position to each other through the conductive portion of the thinned silicon substrate 101, there is a possibility to occur the short circuit between the connection piles 104c and 104d closed in position to each other through the conductive portion of the silicon substrate 101. Thereby, circuits formed in the different integrated circuits 102a and 102b, which are out of the design for electrical connection, are electrically connected to each other. This phenomenon decreases the characteristic of the integrated circuit device and prevents the high integration for the semiconductor integrated circuit device.

### SUMMARY OF THE INVENTION

An object of the present invention is to provide, with due consideration to the drawbacks of the conventional integrated circuit devices and the electronic device described above, an integrated circuit device capable of preventing any occurrence of an electrical connection between circuits formed in integrated circuits of upper and lower layers in a multilayer structure, which are out of the design for electrical connection. Another object of the present invention is to provide an electronic device of a multilayer structure obtained by laminating the plural integrated circuit devices described above.

According to one aspect of the present invention, an integrated circuit device has an integrated circuit formed on a first surface (or a front surface) of a substrate, an insulator, and at least one connection pile. The insulator is formed on a second surface (or a rear surface) opposed to the first surface of the substrate. The connection pile is made of a conductive material filled up in a corresponding hole which penetrates the substrate, the integrated circuit, and the insulator.

### BRIEF DESCRIPTION OF THE DRAWINGS

Other objects, features and advantages of the present invention will become apparent from the following description taken in conjunction with the accompanying drawings, in which:

FIG. 1 is a vertical sectional view of a conventional integrated circuit device;

FIG. 2 is a vertical sectional view of an electronic device made up of two conventional integrated circuit devices which are laminated;

FIG. 3A is a top plan view of an integrated circuit device according to a first embodiment of the present invention;

FIG. 3B is a vertical sectional view taken substantially along line A-A in the integrated circuit device shown in FIG. 3A;

FIG. 3C is a bottom view of the integrated circuit device shown in FIG. 3A;

FIG. 4 is a vertical sectional view of an electronic device made up of the integrated circuit devices which are laminated in a multilayer structure according to the first embodiment of the present invention; and

FIG. 5 is a vertical sectional view of an integrated circuit device according to a second embodiment of the present invention.

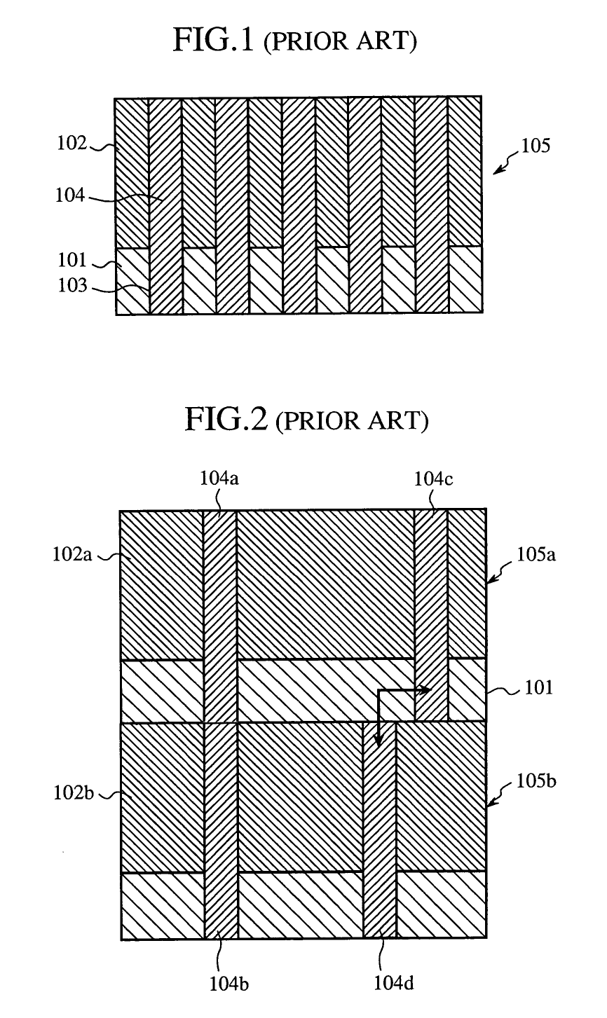

### DETAILED DESCRIPTION OF THE PREFERRED EMBODIMENTS

Embodiments of the present invention will now be described with reference to the accompanying drawings.

First Embodiment

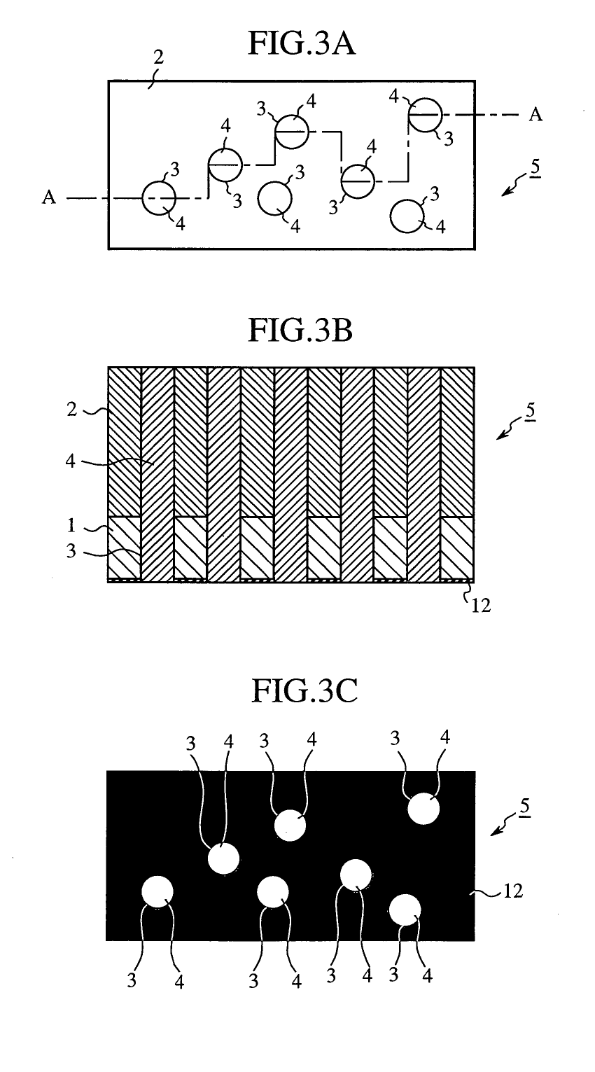

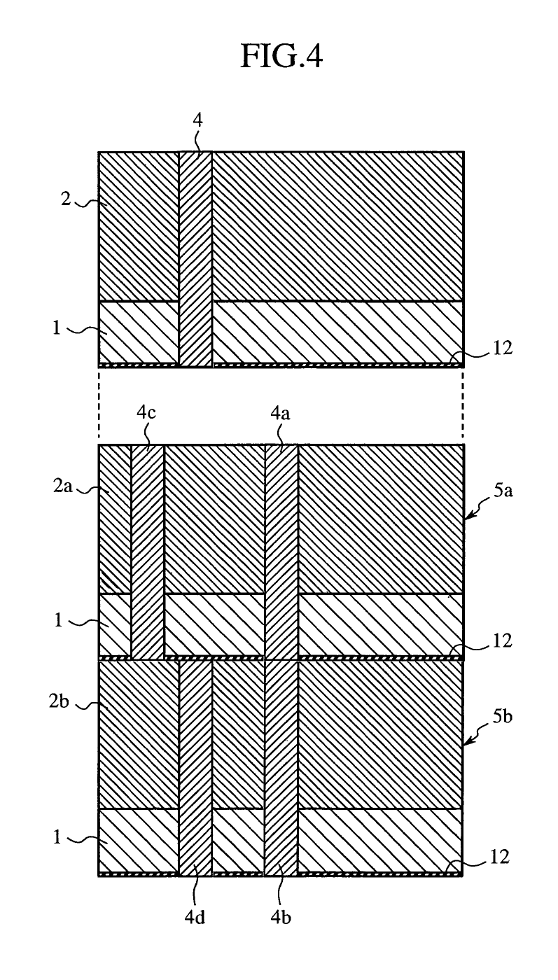

FIG. 3A is a top plan view of an integrated circuit device according to a first embodiment of the present invention. FIG. 3B is a vertical sectional view taken substantially along line A-A in the integrated circuit device shown in FIG. 3A. FIG. 3C is a bottom view of the integrated circuit device shown in FIG. 3A. FIG. 4 is a vertical sectional view of an electronic device made up of the integrated circuit devices which are laminated in a multilayer structure according to the first embodiment of the present invention.

In those figures, reference number 5 designates an integrated circuit device, 1 denotes a thinned silicon (Si) substrate, and 2 indicates an integrated circuit such as a memory circuit or a logic circuit formed on the front surface (as a first surface) of the substrate 1. Reference number 3 designates each of a plurality of connection holes which penetrate the substrate 1 and the integrated circuit 2, and 4 designates each connection pile formed in a corresponding connection hole 3. The connection pile 4 is made of a conductive material such as cupper (Cu).

In a case where a signal is transferred between circuits formed on the integrated circuit 2 and another integrated circuit in the integrated circuit device, the circuit formed on the integrated circuit 2 is electrically connected to the connection pile 4 through a signal line (not shown).

Reference number 12 designates an insulating layer (or an insulator) such as epoxy resin or polyimide, formed on a rear surface (as a second surface) opposed to the front surface of the thinned silicon substrate 1. A plurality of the connection holes 3 and the connection piles 4 are formed so that they penetrate the silicon substrate 1 and the integrated circuit 2 and the insulator layer 12.

Next, a description will now be given of the integrated circuit device fabrication process and the electronic device fabrication process by laminating a plurality of integrated circuits and connecting them electrically.

The configuration of the integrated circuit device 5 shown in FIGS. 3A, 3B, and 3C can provide a high integration function with concentrated functions in a multilayer structure obtained by laminating a plurality of the integrated circuit devices. The connection piles 4 exist only for electrically connecting circuits to each other, which are formed in the integrated circuits 2 in different integrated circuit devices laminated in a multilayer structure.

In the fabrication process for the integrated circuit device 5 shown in FIGS. 3A, 3B, and 3C, the integrated circuit 2 is formed on the front surface of the silicon substrate 1. For example, a memory circuit or/and a logic circuit is formed in the integrated circuit 2.

Following this process, a plurality of the connection holes 3 are formed in the integrated circuits 2 in different layers according to the necessity of the electrical connection between the memory circuit or the logic circuit formed in the different layers of the integrated circuits 2. The connection piles are then formed in the connection holes 3.

Thereafter, the silicon substrate 1 is thinned by removing the rear surface portion of the silicon substrate 1 which is exposed to the atmosphere. As a result, the thinned integrated circuit device 5 is thereby obtained. Accordingly, even if the plural integrated circuit devices are laminated in a multilayer structure, the entire thickness of the integrated circuit devices 5 can be set with a desired value. For example, when the thickness of the silicon substrate 1 is not more than 100 μm, the thickness of each integrated circuit device 5 becomes thinned, so that the number of the integrated circuit devices to be laminated in a multilayer structure can be increased.

Next, an insulating layer 12 is coated on the rear surface of the thinned silicon substrate 1. In this case, no insulating layer 12 is formed on the surface of each connection pile 4. By the presence of the coated insulating layer 12, the thinned silicon substrate 1 is insulated from outside such as another integrated circuit device in a multilayer structure. The fabrication process for the integrated circuit device 5 is thereby complicated.

Furthermore, as shown in FIG. 4, a plurality of the integrated circuit devices 5 are laminated in order to form a multilayer structure. The integrated circuits 2 are electrically connected together through the connection piles 4 formed in the integrated circuit devices 5. The plural integrated circuits 2 are formed in the plural integrated circuit devise 5 in plural layers which are laminated in the multilayer structure.

As an example of the electrical connection between the integrated circuit devices 5a and 5b, we consider a case where a circuit formed in the integrated circuit 2a in the integrated circuit device 5a is electrically connected to a circuit formed in the integrated circuit 2b in the integrated circuit device 5b.

In this case, the connection pile 4a in the integrated circuit device 5a is electrically connected to the circuit formed in the integrated circuit 2a, the connection pile 4b in the integrated circuit device 5b is electrically connected to the circuit formed in the integrated circuit 2b. The integrated circuit device 5a is laminated on the integrated circuit device 5b so that the connection pile 4a is directly and electrically connected to the connection pile 4b. No insulating layer 12 is formed between the connection piles 4a and 4b. The connection pile 4a for the integrated circuit device 5a is electrically connected to the connection pile 4b for the integrated circuit device 5b. Thereby, the circuit formed in the integrated circuit 2a in the integrated circuit device 5a is electrically connected to the circuit formed in the integrated circuit 2b in the integrated circuit device 5b through the connection piles 4a and 4b.

We also consider another case where a circuit formed in the integrated circuit 2a to be electrically connected to the connection pile 4c in the integrated circuit device 5a is not electrically connected to a circuit formed in the integrated circuit 2b to be connected to the connection pile 4d in the integrated circuit device 5b on which the integrated circuit device 5a is laminated. In this case, when the integrated circuit device 5a is laminated on the integrated circuit device 5b, the positioning for the connection piles 4c and 4d is performed so that the connection pile 4c in the integrated circuit device 5a is not electrically connected to the connection pile 4d in the integrated circuit device 5b. Thereby, the connection pile 4d in the integrated circuit device 5b is always and reliably connected to the insulating layer 12 formed on the rear surface of the silicon substrate 1 in the integrated circuit device 5a. Even if the connection pile 4d in the integrated circuit device 5b is closed in position to the connection pile 4c in the integrated circuit device 5a, this connection pile 4d is completely insulated from the connection pile 4c through the insulating layer 12 formed on the rear surface of the integrated circuit device 5a.

Thus, in a case where the connection pile 4 in one integrated circuit 5 is not electrically connected to the connection pile 4 in another integrated circuit device 5, the insulating layer 12 always exists between both the integrated circuit devices 5 laminated in a multilayer structure because the insulating layer 12 is formed on the rear surface of each integrated circuit device 5. Both the connection piles 4 in different integrated circuit devices or in the same integrated circuit device are thereby completely insulated to each other through the insulating layer 12.

When the thickness of the insulating layer 12 is set to not less than 3 nm, it is possible to completely prevent any occurrence of the electrical short between the connection piles 4 which are out of the design for electrical connection.

As described above, according to the first embodiment, although the rear surface of the thinned silicon substrate 1 has conductivity, it is possible to prevent any occurrence of the electrical short between plural connection piles 4 when the positioning is performed so that those connection piles are out of the design of the electrical connection. As a result, it is possible to prevent any electrical connection between the circuits formed in the integrated circuits 2 which are out of the design of the electrical connection. This feature of the integrated circuit device of the present invention can improve the characteristic of the integrated circuit device 5 and promote the integration of the integrated circuit device 5.

Second Embodiment

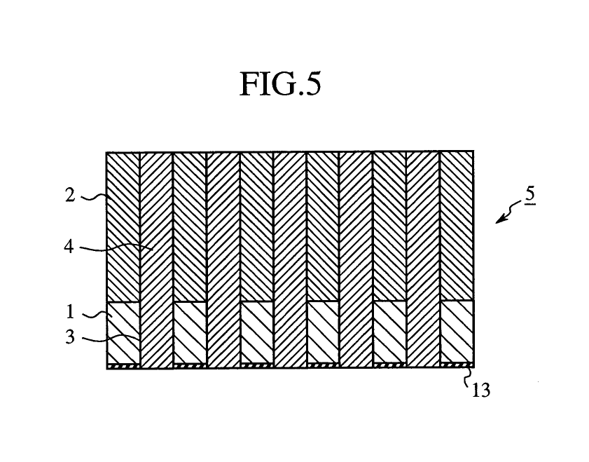

FIG. 5 is a vertical sectional view of an integrated circuit device according to a second embodiment of the present invention. In FIG. 5, the same components of the integrated circuit device of the first embodiment will be referred to the same reference numbers and characters, and the explanation for the same components is omitted here.

In FIG. 5, reference number 13 designates a silicon dioxide film (or an insulator) formed on the rear surface of the thinned silicon substrate 1.

Next, a description will now be given of a fabrication process for the integrated circuit device and a fabrication process for an electronic device in which plural integrated circuits are electrically connected together.

In the fabrication process of the integrated circuit device shown in FIG. 5, after the silicon substrate 1 is thinned by the same manner as described in the first embodiment, the silicon dioxide film 13 is formed on the rear surface of the thinned silicon substrate 1 by oxidizing the rear surface portion of the silicon substrate 1. At this time, no silicon dioxide film 13 is formed on the rear surface of the connection pile 4. Therefore, the thinned silicon substrate 1 is insulated from outside by the silicon dioxide film 13. The fabrication process for the integrated circuit device 5 is thereby completed.

Next, each integrated circuit device 5 is laminated on another integrated circuit device 5 so as to electrically connect a plurality of the integrated circuit devices 5 to each other. The integrated circuits 2 in plural layers are formed in the plural integrated circuit devices 5. When the integrated circuit devices 5 are laminated to each other and some connection piles 4 are out of the design for electrical connection, these connection piles 4 are always connected to the silicon dioxide film 13 formed on the rear surface of the silicon substrate 1 of another integrated circuit device 5. That is, because the silicon dioxide film 13 always exists around the connection piles 4, the connection piles 4 are insulated to each other through the silicon dioxide film 13.

For example, when the thickness of the silicon dioxide film 13 is set to not less than 3 nm, it is completely possible to prevent any occurrence of the electrical short between the connection piles 4.

As described above, according to the second embodiment, although the rear surface portion of the thinned silicon substrate 1 has conductivity, the silicon dioxide film 13 is formed on the rear surface portion of the thinned silicon substrate 1 so as to avoid nay occurrence of the electrical short between the plural connection piles 4 to each other which are out of the design of the electrical connection. This can completely prevent the electrical connection between a circuit formed in the integrated circuit 2 and a circuit formed in another integrated circuit 2 under out of the design of the electrical connection.

This feature can improve the characteristic of the integrated circuit device 5 and promote the integration of the integrated circuit device 5.

As set forth in detail, according to the present invention, the integrated circuit device has an integrated circuit formed on the front surface of a substrate, an insulator formed on the rear surface of the substrate, and connection piles which penetrate the substrate, the integrated circuit, and the insulator. In the electrical connection between the plural integrated circuits which are laminated, the connection piles, which are out of the design of the electrical connection, formed in the integrated circuit device in a lower layer of a multilayer structure are always connected to the insulator formed on the rear surface of the integrated circuit device in an upper layer. It is therefore possible to prevent any occurrence of the electrical connection between the circuits formed in both the integrated circuits in the upper and lower layers. This contributes the high integration or the integrated circuit.

While the above provides a full and complete disclosure of the preferred embodiments of the present invention, various modifications, alternate constructions and equivalents may be employed without departing from the scope of the invention. Therefore the above description and illustration should not be construed as limiting the scope of the invention, which is defined by the appended claims.

What is claimed is:

1. An integrated circuit device comprising:
an integrated circuit formed on a first surface of a substrate;
an insulator formed on a second surface opposed to the first surface of the substrate; and
at least one connection pile made of a conductive material filled up in a corresponding hole which is so formed that it penetrates the substrate, the integrated circuit, and the insulator.

2. The integrated circuit device according to claim 1, wherein a thickness of the insulator is set to not less than 3 nm.

3. The integrated circuit device according to claim 1, wherein a thickness of the substrate is set to not more than 100 μm.

4. The integrated circuit device according to claim 1, wherein a circuit as a target in electrical connection formed in the integrated circuit is electrically connected to the connection pile.

5. An electronic device comprising a plurality of the integrated circuit devices according to claim 1 which are laminated in a multilayer structure,
wherein it is so positioned that a first connection pile is electrically connected to a second connection pile under a requirement of an electric connection for the first and second connection piles formed in first and second integrated circuits, respectively, which are contacted to each other in the multilayer structure, and
wherein it is so positioned the first connection pile is not electrically connected to the second connection pile under no requirement of the electric connection for the first and second connection piles.
